(19) United States
(12) Patent Application Publication
(10) Pub. No.: US 2026/0173636 A1
(43) Pub. Date: Jun. 18, 2026

(54) METHOD FOR IMPROVING WETTABILITY OF CARRIER TRANSPORT LAYER AND PEROVSKITE CELL

(71) Applicant: SHENZHEN HIKING PV TECHNOLOGY CO., LTD., Shenzhen (CN)

(72) Inventors: Yi DONG, Shenzhen (CN); Yang YANG, Shenzhen (CN)

(21) Appl. No.: 19/532,243

(22) Filed: Feb. 6, 2026

Related U.S. Application Data
(63) Continuation of application No. PCT/CN2024/123856, filed on Oct. 10, 2024.

(30) Foreign Application Priority Data
Jan. 17, 2024 (CN) 202410066101.2

(51) Int. Cl. H10K 30/57; H10K 30/40; H10K 71/15

(52) U.S. Cl. CPC H10K 30/57; H10K 30/40; H10K 71/15

(57) ABSTRACT

The present invention provides a method for improving wettability of a carrier transport layer and a perovskite cell. A passivation layer of the carrier transport layer is coated onto a substrate by using a wet coating process; and after the passivation layer of the carrier transport layer is heated and annealed, a modified solvent is rapidly coated onto the passivation layer of the carrier transport layer in a non-contact manner. Residual heat is used to evaporate the modified solvent until dry, causing a layer of polar hydrophilic groups to be adhered to the passivation layer of the carrier transport layer, thereby improving wettability thereof.

### CROSS-REFERENCE TO RELATED APPLICATIONS

The present application is a continuation of International Application No. PCT/CN2024/123856, filed on Oct. 10, 2024, which claims priority to Chinese Patent Application No. 202410066101.2, filed on Jan. 17, 2024, the entire disclosure of which is incorporated herein by reference.

### FIELD OF TECHNOLOGY

The present invention belongs to the technical field of perovskite, and specifically relates to a method for fabricating a modified layer on a carrier transport layer to improve wettability between a perovskite ink and the carrier transport layer, thereby enhancing the performance of perovskite or crystalline silicon/perovskite tandem solar cells.

### BACKGROUND

Statements herein are provided merely as background information relevant to this application and do not necessarily constitute the prior art.

Perovskite solar cells are solar cells that utilize perovskite-type organic metal halide semiconductors as light-absorbing materials and are classified as third-generation solar cells. The perovskite solar cells are currently one of the most promising solar cells due to their high photoelectric conversion efficiency, low cost, and simple fabrication process. The perovskite cells have a simple structure, with a typical configuration from bottom to top as follows: an electrode layer, a carrier transport layer, a perovskite layer, a carrier transport layer, and an electrode layer. The carrier transport layer can be generally divided into a hole transport layer or an electron transport layer. The hole transport layer, as an important component of the perovskite solar cells, primarily functions to collect and transport holes, achieve effective electron-hole separation, and protect the perovskite layer from corrosion by oxygen and moisture, thereby significantly affecting cell efficiency and stability. The electron transport layer, as an important component of the perovskite cells, plays a crucial role in extracting and transporting photogenerated electrons, blocking holes, modifying interfaces, adjusting interface energy levels, and reducing carrier recombination. Due to common problems such as energy level mismatch and interfacial defects between perovskite active layers, various types of passivation materials are currently added to a single carrier transport layer to form a passivation layer of the carrier transport layer. This enhances interfacial carrier transfer, suppresses carrier recombination caused by defects, reduces energy loss during carrier transport, improves the performance and stability of a device, and thus increases the energy conversion efficiency of the device.

However, the passivation layer of the carrier transport layer exhibits strong hydrophobicity, resulting in insufficient wettability of a perovskite solution on this layer. It is difficult to obtain a dense and smooth perovskite film, and improper interfacial contact between the hydrophobic passivation layer and the perovskite leads to numerous voids in the fabricated perovskite film, which impairs the performance and stability of a solar device.

### SUMMARY

To overcome the shortcomings of the prior art, the present invention provides a method for improving wettability of a carrier transport layer. A passivation layer of the carrier transport is coated onto the carrier transport layer by using a wet coating process; and after the passivation layer of the carrier transport is heated and annealed, a modified solvent is rapidly coated onto a passivation layer of the carrier transport layer. Residual heat is used to evaporate the modified solvent until dry, causing a layer of polar hydrophilic groups to be adhered to the passivation layer of the carrier transport layer, thereby improving wettability thereof, reducing interfacial defects of the fabricated perovskite film on the passivation layer, and enhancing film stability and uniformity.

A first aspect of the present invention provides a method for improving wettability of a carrier transport layer, and the method is applied to a cell and includes the following steps:
Step 1: providing a cell substrate and fabricating the carrier transport layer on the cell substrate;
Step 2: fabricating a passivation layer of the carrier transport layer on the carrier transport layer;
Step 3: providing a modified solvent, and within 2 s to 120 s after completion of Step 2, rapidly coating the modified solvent onto the passivation layer of the carrier transport layer in a non-contact manner, with a dosage of the modified solvent controlled at 0.1 uL/cm² to 50 uL/cm²; and
Step 4: fabricating a perovskite film with a thickness of 700 nm on the passivation layer of the carrier transport layer by slot coating.

Optionally, the modified solvent should satisfy the following three conditions:
1, a boiling point: 70° C. to 250° C.;
2, the modified solvent includes hydrophilic polar groups, and the hydrophilic polar groups are at least one of hydroxyl (—OH), carboxyl (—COOH), amide group, amino (—NH2), aldehyde (—CHO), or carbonyl (—CO); and
3, a viscosity range: 1 cp to 500 cp.

Optionally, the modified solvent is generally at least one from dimethyl sulfoxide, N,N-dimethylformamide, deionized water, or ethanol.

Optionally, the carrier transport layer is deposited by using one or more processes selected from vacuum coating or atomic layer deposition in a dry process, as well as spray coating, slot coating, and spin coating in a wet process, and the carrier transport layer is composed of at least one of NiO, PTAA, 2PACz, 4PACz, SnO₂, TiO₂, with a thickness of 0 nm to 50 nm.

Specifically, NiO is selected as a material of the carrier transport layer, and a 50 nm NiO film is fabricated as the carrier transport layer by magnetron sputtering as a deposition method.

Specifically, the passivation layer of the carrier transport layer is prepared by coating a passivation layer solution onto the carrier transport layer and performing annealing, and the passivation layer solution is obtained by dissolving a passivation layer material in a passivation layer solvent.

The passivation layer material may be conjugated polymers, self-assembled monolayers (SAMs), or a composite of one or more materials, specifically including at least one of PTAA, 2PACz, 4PACz, and Meo-4Pacz; and the passivation layer solvent includes but is not limited to one or more of ethanol, methanol, and chlorobenzene.

Preferably, in the embodiment of the present invention, PTAA is selected as the passivation layer material and chlorobenzene is selected as the passivation layer solvent to prepare a passivation layer solution with a concentration of 0.2 mg/mL.

Optionally, the passivation layer of the carrier transport layer may be deposited by one of spray coating, slot coating, or spin coating.

Optionally, a heating and annealing temperature after the passivation layer solution is coated and deposited into a film is 80° C. to 250° C., and an annealing time thereof is 5 min to 50 min. During heating, a material of the passivation layer of the carrier transport layer is tightly bonded to a material of the carrier transport layer and does not react with the subsequent modified solvent.

Preferably, an annealing time of the passivation layer of the carrier transport layer is 28 min, and an annealing temperature thereof is 170° C.

Optionally, a non-contact coating method for the modified solvent may be a rapid coating process in which the modified solvent does not contact with the substrate such as slot coating or spray coating. The coating process is completed within 5 s to 30 s. To ensure complete evaporation of residual heat, the amount of the modified solvent on the substrate is controlled at 4 uL/cm².

Optionally, to maintain the residual heat of the substrate at 80° C. to 240° C., an interval time from completion of the annealing process of the passivation layer of the carrier transport layer to a coating process of the modified solvent need be within 1 s to 100 s.

Optionally, in Step 4, the temperature of the substrate need be maintained at 80° C. to 240° C. If the temperature is too low, the modified solvent cannot fully evaporate, and excessive residual heat will cause damage to the hydrophilic modified groups.

Optionally, the method of coating the perovskite film onto the modified passivation layer of the carrier transport layer may be a wet process such as slot coating, spray coating, blade coating, or screen printing.

A second aspect of an embodiment of the present invention provides a perovskite cell, and the cell is prepared by the above method for improving wettability of a carrier transport layer and includes: a glass substrate, a first electrode layer, the carrier transport layer, the passivation layer of the carrier transport layer, the perovskite film, a second carrier transport layer, and a second electrode layer.

A third aspect of an embodiment of the present invention provides a perovskite/crystalline silicon tandem cell, and the cell is prepared by the above method for improving wettability of a carrier transport layer and includes: a first metal electrode layer, a first transparent electrode layer, a silicon substrate, a second transparent electrode layer, the carrier transport layer, the passivation layer of the carrier transport layer, the perovskite film, a second carrier transport layer, a third transparent electrode layer, and a second metal electrode layer.

In the process of the present invention, the modified solvent is directly coated onto the annealed passivation layer of the carrier transport layer, and the solvent is rapidly evaporated by using the residual heat to fabricate the modified layer. Wettability between a perovskite ink and the passivation layer of the carrier transport layer is improved, thereby significantly reducing defects of a perovskite absorption layer and improving the smoothness thereof. The process of the present invention requires no additional annealing equipment, is simple and efficient, and is suitable for a process route of improving wettability of the carrier transport layer during industrial production.

### BRIEF DESCRIPTION OF THE DRAWINGS

In order to more clearly explain embodiments of the present invention or the technical solution in the prior art, the accompanying drawings needed in the descriptions of the embodiments or the prior art will be briefly introduced below. Apparently, the accompanying drawings in the following descriptions are only some embodiments of the present invention. Other accompanying drawings also may be obtained by ordinary persons skilled in the art based on these drawings without any creative labor.

FIG. 1 is a flowchart of steps of a method for improving wettability of a carrier transport layer provided in an example of the present invention;

FIG. 2 is a schematic structural diagram of a single-junction perovskite cell in Example 1 of the present invention; and

FIG. 3 is a schematic structural diagram of a perovskite/crystalline silicon tandem cell in Example 1 of the present invention.

### DESCRIPTION OF THE EMBODIMENTS

In order to make the technical problems to be solved, technical solutions, and beneficial effects of the present invention clearer and more understandable, the following provides a further detailed description of the present invention in conjunction with the accompanying drawings and embodiments. It should be understood that specific embodiments described herein are merely intended for explaining the present invention, instead of limiting the present invention.

It should be noted that when an element is referred to as “fixed to” or “disposed on” another element, it may be directly connected to the another element or indirectly connected to the another element. When an element is referred to as “connected to” another element, it may be directly connected to the another element or indirectly connected to the another element.

Furthermore, the terms “first” and “second” are used merely for descriptive purposes and should not be construed as indicating or implying relative importance, nor should they be understood to imply the number of technical features indicated. Accordingly, features defined as “first” or “second” may explicitly or implicitly include one or more such features. In the description of the present invention, “a plurality of” means two or more unless otherwise specifically defined. “Several” means one or more unless otherwise specifically defined.

In the description of the present invention, it should be understood that orientations or positional relationships indicated by the terms such as “center,” “length,” “width,” “thickness,” “upper,” “lower,” “front,” “rear,” “left,” “right,” “vertical,” “horizontal,” “top,” “bottom,” “inner,” “outer,” and the like are based on the orientation or positional relationships as shown in the accompanying drawings. These terms are merely for ease and brevity of description of the present invention rather than indicating or implying that the apparatuses or components mentioned must have specific orientations or must be constructed or manipulated according to specific orientations, and therefore shall not be construed as any limitations on embodiments of the present invention.

In the description of the present invention, unless otherwise expressly specified or defined, the terms “mounted,” “connected,” and “joined” should be interpreted broadly. For example, the connections may be fixed connections, detachable connections, or integral connections; the connections may be mechanical connections or electrical connections; and the connections may be direct connections or indirect connections via an intermediate medium, an internal communication between two elements or interaction between two elements. For those skilled in the art, the specific meanings of the above terms in the present invention can be understood according to the specific circumstances.

Reference to “one embodiment” or “an embodiment” throughout the specification means that a particular feature, structure, or characteristic described with reference to the embodiments is incorporated in at least one embodiment of the present invention. Therefore, the phrase “in one embodiment” or “in some embodiments” used in different parts of this specification does not necessarily refer to a same embodiment. Moreover, in one or more embodiments, specific features, structures, or characteristics may be combined in any suitable manner.

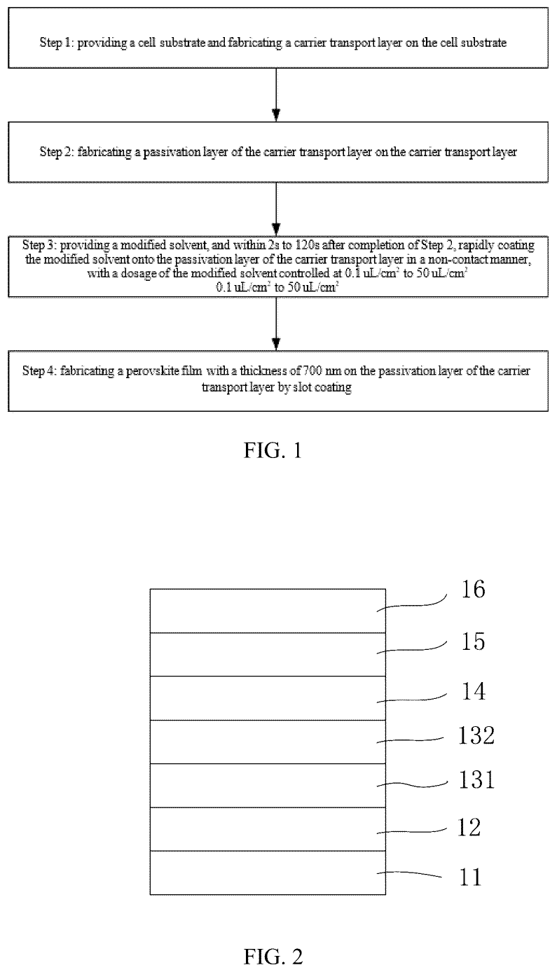

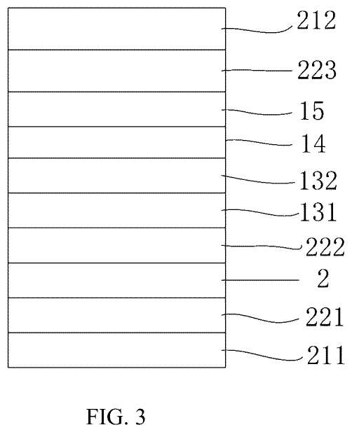

Refer to FIG. 1 to FIG. 3. One aspect of the present invention provides a method for improving wettability of a carrier transport layer, and the method is applied to a perovskite cell or perovskite/crystalline silicon tandem cell, and includes the following steps:
Step 1: providing a cell substrate and fabricating the carrier transport layer on the cell substrate 131.

Optionally, the carrier transport layer 131 is deposited from one or more materials including, but not limited to, NiO, SnO₂, TiO₂, and 2PACz by processes such as magnetron sputtering, evaporation, spray coating, or slot coating. Specifically, in the embodiment of the present invention, NiO is selected as the material of the carrier transport layer 131, and a 50 nm NiO film is fabricated as the carrier transport layer 131 by magnetron sputtering as a deposition method.
Step 2: fabricating a passivation layer 132 of the carrier transport layer on the carrier transport layer 131.

Specifically, the passivation layer 132 of the carrier transport layer is prepared by spray coating the passivation layer solution onto the carrier transport layer 131, and then annealed at a temperature of 170° C. for 28 min. The passivation solution is obtained by dissolving the passivation layer material in the passivation layer solvent. The passivation layer material includes but is not limited to one or more of PTAA, 2PACz, 4PACz, Meo-4Pacz, and the like, and the passivation layer solvent includes but is not limited to one or more of ethanol, methanol, chlorobenzene, and the like. In the embodiment of the present invention, PTAA is selected as the passivation layer material and chlorobenzene is selected as the passivation layer solvent to prepare a passivation layer solution with a concentration of 0.2 mg/mL.
Step 3: providing a modified solvent, and within 2 s to 120 s after completion of Step 2, rapidly coating the modified solvent onto the passivation layer 132 of the carrier transport layer by slot coating, with a dosage of the modified solvent controlled at 0.1 μL/cm² to 15 μL/cm². The modified solvent coated onto the passivation layer 132 of the carrier transport layer rapidly evaporates under residual heat, leaving only a small amount of hydrophilic groups and completing the modification.

Optionally, the modified solvent may be selected according to the following criteria:
1, a boiling point: 70° C. to 250° C.;
2, the modified solvent includes hydrophilic polar groups, such as hydroxyl (—OH), carboxyl (—COOH), amide group, amino (—NH2), aldehyde (—CHO), and carbonyl (—CO);
3, a viscosity range: 1 cp to 500 cp (excessively high or low viscosity will affect coating coverage).

In the embodiment of the present invention, the modified solvent is one or more of dimethyl sulfoxide, N,N-dimethylformamide (DMF), deionized water, or ethanol.
Step 4: fabricating a perovskite film 14 with a thickness of 700 nm on the passivation layer 132 of the carrier transport layer by slot coating.

A second aspect of an embodiment of the present invention provides a perovskite cell, and the cell is prepared by the above method for improving wettability of a carrier transport layer and includes: a glass substrate 11, a first electrode layer 12, the carrier transport layer 131, the passivation layer 132 of the carrier transport layer, the perovskite film 14, a second carrier transport layer 15, and a second electrode layer 16.

A third aspect of an embodiment of the present invention provides a perovskite/crystalline silicon tandem cell, and the cell is prepared by the above method for improving wettability of a carrier transport layer and includes: a first metal electrode layer 211, a first transparent electrode layer 221, a silicon substrate 2, a second transparent electrode layer 222, the carrier transport layer 131, the passivation layer 132 of the carrier transport layer, the perovskite film 14, a second carrier transport layer 15, a third transparent electrode layer 223, and a second metal electrode layer 212.

To verify that the process of the embodiment of the present invention can significantly improve the fabrication of single-junction perovskite solar cells. The present invention provides Example 1 and three comparative examples for demonstration.
Example 1: refer to FIG. 2. The embodiment provides a single-junction perovskite solar cell 1, and the cell includes, from bottom to top, a glass substrate 11, a first electrode layer 12, the carrier transport layer 131, the passivation layer 132 of the carrier transport layer, the perovskite film 14, a second carrier transport layer 15, and a second electrode layer 16. Specific preparation steps include:
Step 1: select a glass substrate 11 made of high-transmittance conductive glass and a first electrode layer 12 as a cell substrate. A thickness of the glass substrate 11 is 0.5 mm to 5 mm, and the first electrode layer 12 is made of fluorine-doped tin oxide (FTO) with a thickness of 10 nm to 1000 nm. Specifically, a thickness of the glass substrate 11 is 2.2 mm, and a thickness of the first electrode layer 12 is 300 nm;
Step 2: prepare NIOₓ as the carrier transport layer 131 on the first electrode layer 12 by magnetron sputtering. Preferably, a thickness of NIOₓ is 8 nm;
Step 3: dissolve Meo-2pacz in an ethanol solvent to obtain a passivation layer solution with a concentration of 5 mg/ml;
Step 4: coat the passivation layer solution prepared in Step 3 onto the carrier transport layer 131 through slot coating, and anneal the coated passivation layer wet film at 150° C. for 20 min to obtain the passivation layer 132 of the carrier transport layer;
Step 5: 5 s after the passivation layer 132 of the carrier transport layer is annealed and at a substrate temperature of 135° C., coat a DMF-free modified solvent onto the passivation layer 132 of the carrier transport layer through spray coating at a liquid volume of 4 μL/cm² and a coating time of 5 s. The modified solvent fully evaporates by the residual heat of the substrate at 135° C., leaving hydroxyl (—OH) hydrophilic groups and completing the modification;
Step 6: fabricate a perovskite film 14 with a thickness of 700 nm on the passivation layer 132 of the carrier transport layer through slot coating;
Step 7: select C₆₀ and SnO₂ as a second carrier transport layer 15, and sequentially deposit C₆₀ with a thickness of 34 nm and SnO₂ with a thickness of 20 nm onto the perovskite film 14 by evaporation; and
Step 8: make copper with a thickness of 150 nm evaporate on the second carrier transport layer 15 as the second electrode layer 16 to complete the cell fabrication.
Comparative Example 1: the comparative example provides a single-junction perovskite cell. The cell has a same cell structure as that in Example 1, and includes, from bottom to top, a glass substrate 11, a first electrode layer 12, a carrier transport layer 131, a perovskite film 14, a second carrier transport layer 15, and a second electrode layer 16. A difference between Comparative Example 1 and Example 1 is that Step 5 is omitted in this comparative example, that is, no modification treatment is performed on the passivation layer 132 of the carrier transport layer.
Comparative Example 2: the comparative example provides a single-junction perovskite cell without a passivation structure, and the cell includes, from bottom to top, a glass substrate 11, a first electrode layer 12, a carrier transport layer 131, a perovskite film 14, a second carrier transport layer 15, and a second electrode layer 16. A difference between Comparative Example 2 and Example 1 is that Steps 4 and 5 are omitted in the comparative example, that is, no passivation or modification treatment is performed on the carrier transport layer 131.
Comparative Example 3: the comparative example provides a single-junction perovskite cell without a carrier transport structure. The cell structure includes, from bottom to top, a glass substrate 11, a first electrode layer 12, a passivation layer of the carrier transport layer 132, a perovskite absorber layer 14, a second carrier transport layer 15, and a second electrode layer 16. A difference between Example 1 and Comparative Example 3 is that Step 2 is omitted in the comparative example, and an original carrier transport structure is replaced by the modified passivation layer.

A comparative experiment was conducted between Example 1 of the present invention and Comparative Examples 1 to 3. A solar simulator was used for standard solar intensity calibration, and long-term IV testing was performed on comparative devices with an area of 1.0 cm². An initial voltage was set to 0 V, a cutoff voltage was 1.3 V, and a range was 100 mA. The test results are shown in the table below.

| | | | | Photoelectric |
|---|---|---|---|---|
| | Short-circuit | Open-circuit | Packing | conversion |
| | current density/Jsc | voltage/Voc | factor/FF | efficiency/ |
| Device | (mA/cm²) | (mV) | (%) | PCE (%) |
| Example 1 | 20.88 | 1.21 | 82.4 | 20.81 |
| Comparative | 16.55 | 0.984 | 56.7 | 9.23 |
| Example 1 | | | | |
| Comparative | 19.55 | 1.09 | 79.5 | 17.4 |
| Example 2 | | | | |
| Comparative | 18.54 | 1.03 | 75.5 | 14.41 |
| Example 3 | | | | |

It can be seen from the comparison in the above table that:
1. Comparison between Example 1 and Comparative Example 1 shows that failure to modify the surface of the passivation layer with the modified solvent will result in uneven coverage of the passivation layer surface by the wet film of the perovskite layer during fabrication, accompanied by many pinholes, failure to form a dense light-absorbing layer, and excessive cell defects.
2. Comparison between Example 1 and Comparative Example 2 shows that although a conventional carrier transport layer material has no wettability problem, the cell obtained without passivation of the carrier transport layer has lower open-circuit voltage and packing factor, resulting in poor cell performance.
3. Comparison between Example 1 and Comparative Example 3 shows that an organic passivation layer material with wettability improved by a solvent still cannot fully replace the carrier transport layer. The photo-induced passivation effect of Comparative Examples 1 to 3 is inferior to that of Example 1 of the present invention.

In comparison, Example 1 of the present invention exhibits higher open-circuit voltage and photoelectric conversion efficiency.

To verify that the process of the embodiment of the present invention can significantly improve the fabrication of crystalline silicon/perovskite tandem cells, Example 2 and three comparative examples are provided below for demonstration.
Example 2: an embodiment of the present invention provides a perovskite/crystalline silicon tandem cell, and the cell includes, from bottom to top, a first metal electrode layer 211, a first transparent electrode layer 221, a silicon substrate 2, a second transparent electrode layer 222, a carrier transport layer 131, a passivation layer of a carrier transport layer 132, a perovskite film 14, a second carrier transport layer 15, a third transparent electrode layer 223, and a second metal electrode layer 212. Specific preparation steps include:
Step 1: prepare the first transparent electrode layer 221 on the silicon substrate 2. Optionally, by means of magnetron sputtering, the silicon substrate 2 is placed in a magnetron sputtering apparatus, an ITO (Indium Tin Oxide) target material is loaded, and a sputtering power is controlled within a range of 10 W to 400 W. Specifically, in the embodiment of the present invention, the power is controlled at 85 W, an operation time is 0.8 h, and a thickness of the first transparent electrode layer 221 is 80 nm.
Step 2: prepare the first metal electrode layer 211 on the first transparent electrode layer 221. Optionally, by means of evaporation, the prepared substrate sample is placed on a mask plate and put into an evaporator chamber, an evaporation vacuum is 1×10⁻⁵ Pa to 1×10⁻³ Pa, an evaporation temperature is 200° C. to 2000° C., and an evaporation rate is 0.1 Å/s to 50 Å/s. Specifically, in the embodiment of the present invention, evaporation is performed at an evaporation vacuum of 8×10⁻⁴ Pa, an evaporation voltage is adjusted to reach the evaporation temperature, the evaporation rate is controlled at 1.5 Å/s, and silver is evaporated onto a film layer to form a silver layer with a thickness of 120 nm.
Step 3: prepare the second transparent electrode layer 222 on the other side of the silicon substrate 2. Optionally, by means of magnetron sputtering, the above silicon substrate sample is placed in the magnetron sputtering apparatus, the ITO (Indium Tin Oxide) target material is loaded, and the sputtering power is controlled within ta range of 10 W to 400 W. Specifically, in the embodiment of the present invention, the power is controlled at 70 W, the operation time is 1 h, and a film thickness is 40 nm.
Step 4: prepare NIOₓ as the carrier transport layer 131 on the surface of the second transparent electrode layer 222 by magnetron sputtering. Preferably, a thickness of NIOₓ is 8 nm.
Step 5: prepare the passivation layer solution for the passivation layer 132 of the carrier transport layer. Specifically, dissolve Meo-2pacz in ethanol to obtain the passivation layer solution with a concentration of 5 mg/mL.
Step 6: coat the passivation layer solution prepared in Step 5 onto the carrier transport layer 131 through slot coating, and anneal the coated passivation layer wet film at 150° C. for 20 min to obtain the passivation layer 132 of the carrier transport layer.
Step 7: 5 s after the passivation layer 132 of the carrier transport layer is annealed at 150° C. and at a substrate temperature of 135° C., coat a DMF-free modified solvent onto the passivation layer 132 of the carrier transport layer through spray coating at a liquid volume of 4 μL/cm² and a coating time of 5 s. The modified solvent fully evaporates by the residual heat of the substrate at 135° C., leaving hydroxyl (—OH) hydrophilic groups and completing the modification.
Step 8: fabricate a perovskite film 14 with a thickness of 700 nm on the passivation layer 132 of the carrier transport layer by slot coating.
Step 9: select C₆₀ and SnO₂ as a second carrier transport layer 15, and sequentially deposit C₆₀ with a thickness of 34 nm and SnO₂ with a thickness of 20 nm onto the perovskite film 14 by evaporation; and
Step 10: fabricate the third transparent electrode layer 223 on the second carrier transport layer 15.

Optionally, by means of magnetron sputtering, a transparent electrode material is sputtered onto the surface of the above second carrier transport layer 14, with a sputtering power controlled at 30 W to 200 W.
Step 11: prepare the second metal electrode layer 212 on the third transparent electrode layer 223. Specifically, the preparation method of the second metal electrode layer is similar to that of the first metal electrode layer 211, and only the mask plate is different with a thickness of 100 nm.
Comparative Example 4: Comparative Example 4 provides perovskite/crystalline silicon tandem cell with a same device structure as that in Example 2, and the cell includes, from bottom to top, a first metal electrode layer 211, a first transparent electrode layer 221, a silicon substrate 2, a second transparent electrode layer 222, a carrier transport layer 131, a passivation layer 132 of the carrier transport layer, a perovskite film 14, a second carrier transport layer 15, a third transparent electrode layer 223, and a second metal electrode layer 212. A difference between Comparative Example 4 and Example 2 is that Step 7 is omitted in the comparative example, that is, the passivation layer of the carrier transport layer 132 is not modified.
Comparative Example 5: Comparative Example 5 provides a perovskite/crystalline silicon tandem cell without a passivation layer structure, and the cell includes, from bottom to top, a first metal electrode layer 211, a first transparent electrode layer 221, a silicon substrate 2, a second transparent electrode layer 222, a carrier transport layer 131, a perovskite film 14, a second carrier transport layer 15, a third transparent electrode layer 223, and a second metal electrode layer 212. A difference between Comparative Example 5 and Example 2 is that Steps 5 and 6 are omitted in the comparative example, that is, the carrier transport layer 131 is not subjected to passivation treatment, and modification and preparation of the perovskite film 14 are carried out directly on the carrier transport layer.
Comparative Example 6: Comparative Example 6 provides a perovskite/crystalline silicon tandem cell without a carrier transport structure, and the cell includes, from bottom to top, a first metal electrode layer 211, a first transparent electrode layer 221, a silicon substrate 2, a second transparent electrode layer 222, a passivation layer of the carrier transport layer 132, a perovskite film 14, a second carrier transport layer 15, a third transparent electrode layer 223, and a second metal electrode layer 212. A difference between Comparative Example 6 and Example 2 is that Step 4 is omitted in the comparative example, that is, the modified passivation layer 132 of the carrier transport layer is used to replace a carrier transport structure.

A comparative experiment was conducted between Example 2 of the present invention and Comparative Examples 4 to 6. A solar simulator was used for standard solar intensity calibration, and long-term IV testing was performed on comparative devices with an area of 1.0 cm². An initial voltage was set to 0 V, a cutoff voltage was 2.0 V, and a range was 100 mA. The test results are shown in the table below.

| | | | | Photoelectric |
|---|---|---|---|---|
| | Short-circuit | Open-circuit | Packing | conversion |
| | current density/Jsc | voltage/Voc | factor/FF | efficiency/ |
| Device | (mA/cm²) | (mV) | (%) | PCE (%) |
| Example 2 | 19.56 | 1.92 | 80.02 | 30.05 |
| Comparative | 17.36 | 1.80 | 70.65 | 22.07 |
| Example 4 | | | | |
| Comparative | 19.04 | 1.77 | 76.34 | 25.73 |
| Example 5 | | | | |
| Comparative | 18.90 | 1.86 | 70.13 | 24.65 |
| Example 6 | | | | |

It can be seen from the comparison in the above table that:
1. Comparison between Example 2 and Comparative Example 4 shows that improving the surface of the passivation layer with the modified solvent can improve the wettability of the perovskite layer during fabrication, allowing the perovskite wet film to uniformly cover the surface of the passivation layer and forming a dense, pinhole-free light-absorbing layer. Test results of Example 2 also exhibit a higher packing factor.
2. Comparison between Example 2 and Comparative Example 5 shows that although a conventional carrier transport layer material has no wettability problem, the cell obtained without passivation of the carrier transport layer has lower open-circuit voltage and packing factor, resulting in poor cell performance.
3. Comparison between Example 2 and Comparative Example 6 shows that an organic passivation layer material with wettability improved by a solvent still cannot fully replace the carrier transport layer. The photo-induced passivation effect of Comparative Examples 4 to 6 is inferior to that of the example of the present invention.

In comparison, Example 2 of the present invention exhibits higher open-circuit voltage and photoelectric conversion efficiency.

The above description is merely an optional embodiment of this application and is not intended to limit this application. Any modification, equivalent replacement, improvement, or the like made without departing from the spirit and principle of this application shall fall within the protection scope of this application.

What is claimed is:

1. A method for improving wettability of a carrier transport layer, applied to a cell, comprising the following steps:
Step 1: providing a cell substrate and fabricating the carrier transport layer on the cell substrate;
Step 2: fabricating a passivation layer of the carrier transport layer on the carrier transport layer;
Step 3: providing a modified solvent, and within 2 s to 120 s after completion of Step 2, rapidly coating the modified solvent onto the passivation layer of the carrier transport layer in a non-contact manner, with a dosage of the modified solvent controlled at 0.1 uL/cm² to 50 uL/cm²; and
Step 4: fabricating a perovskite film with a thickness of 700 nm on the passivation layer of the carrier transport layer by slot coating.

2. The method for improving wettability of a carrier transport layer according to claim 1, wherein the modified solvent satisfies the following conditions:
a boiling point: 70° C. to 250° C.;
the modified solvent comprises hydrophilic polar groups, and the hydrophilic polar groups are at least one of hydroxyl (—OH), carboxyl (—COOH), amide group, amino (—NH2), aldehyde (—CHO), or carbonyl (—CO); and
a viscosity range: 1 cp to 500 cp.

3. The method for improving wettability of a carrier transport layer according to claim 2, wherein the modified solvent is at least one from dimethyl sulfoxide, N,N-dimethylformamide, deionized water, or ethanol.

4. The method for improving wettability of a carrier transport layer according to claim 1, wherein the carrier transport layer is deposited by using one or more processes selected from vacuum coating or atomic layer deposition in a dry process, as well as spray coating, slot coating, and spin coating in a wet process, and the carrier transport layer is composed of at least one of NiO, PTAA, 2PACz, 4PACz, SnO₂, TiO₂, with a thickness of 0 nm to 50 nm.

5. The method for improving wettability of a carrier transport layer according to claim 4, wherein NiO is selected as a material of the carrier transport layer, and a 50 nm NiO film is fabricated as the carrier transport layer by magnetron sputtering as a deposition method.

6. The method for improving wettability of a carrier transport layer according to claim 1, wherein the passivation layer of the carrier transport layer is fabricated by coating a passivation layer solution onto the carrier transport layer and performing annealing, and the passivation layer solution is obtained by dissolving a passivation layer material in a passivation layer solvent.

7. The method for improving wettability of a carrier transport layer according to claim 6, wherein the passivation layer material is a composite of one or more materials selected from conjugated polymers and self-assembled monolayers (SAMs); and the passivation layer solvent comprises, but is not limited to, one or more of ethanol, methanol, or chlorobenzene.

8. The method for improving wettability of a carrier transport layer according to claim 1, wherein a non-contact coating method for the modified solvent is at least one of slot coating or spray coating, the coating process is completed within 5 s to 30 s, and the dosage of the modified solvent on a substrate is controlled at 4 uL/cm².

9. The method for improving wettability of a carrier transport layer according to claim 6, wherein an interval time from completion of the annealing process of the passivation layer of the carrier transport layer to a coating process of the modified solvent is within 1 s to 100 s.

10. A perovskite cell prepared by the method for improving wettability of a carrier transport layer according to claim 1, sequentially comprising, from bottom to top, a glass substrate, a first electrode layer, the carrier transport layer, the passivation layer of the carrier transport layer, the perovskite film, a second carrier transport layer, and a second electrode layer.

11. A perovskite/crystalline silicon tandem cell prepared by the method for improving wettability of a carrier transport layer according to claim 1, sequentially comprising, from bottom to top, a first metal electrode layer, a first transparent electrode layer, a silicon substrate, a second transparent electrode layer, the carrier transport layer, the passivation layer of the carrier transport layer, the perovskite film, a second carrier transport layer, a third transparent electrode layer, and a second metal electrode layer.
